(19) United States
(12) Patent Application Publication
(10) Pub. No.: US 2024/0334604 A1
(43) Pub. Date: Oct. 3, 2024

(54) METHOD FOR LOCATING HALL EFFECT SENSOR ASSEMBLY

(71) Applicant: Honeywell Federal Manufacturing & Technologies, LLC, Kansas City, MO (US)

(72) Inventor: Lucas Alan Mann, Kansas City, MO (US)

(73) Assignee: Honeywell Federal Manufacturing & Technologies, LLC, Kansas City, MO (US)

(21) Appl. No.: 18/126,742

(22) Filed: Mar. 27, 2023

(51) Int. Cl. H05K 1/18; G01D 5/14; H05K 1/02

(52) U.S. Cl. CPC H05K 1/181; G01D 5/147; H05K 1/0259

(57) ABSTRACT

A method of locating a Hall Effect sensor assembly, the method broadly comprising steps of effecting relative movement between a magnetic device and a Hall Effect sensor of the Hall Effect sensor assembly, querying the Hall Effect sensor as the relative movement is effected, monitoring an output of the Hall Effect sensor in response to the querying step, identifying a functional center of the Hall Effect sensor assembly based on a peak of the output of the Hall Effect sensor, and indicating the functional center of the Hall Effect sensor assembly via a substrate of the Hall Effect sensor assembly for integrating the Hall Effect sensor assembly into a circuit assembly.

### GOVERNMENT INTERESTS

This invention was made with Government support under Contract No.: DE-NA-0002839 awarded by the United States Department of Energy/National Nuclear Security Administration. The Government has certain rights in the invention.

### BACKGROUND

Many Hall Effect sensors are electrostatic discharge (ESD) sensitive and are typically custom-added to electronic circuit assemblies. Ensuring Hall Effect sensors are sufficiently protected from ESD and properly integrated into the electronic circuit assemblies via customized footprints or layouts adds significant turnaround time.

Proper integration of Hall Effect sensors and/or Hall Effect sensor assemblies into electronic circuit assemblies requires correctly positioning their functional centers relative to the electronic circuit assemblies. In this effort, conventional sensor placement produces a tolerance stack arising from PCB size, pad location and pad size, tolerances within the Hall Effect sensor, and physical placement of the Hall Effect sensor, which results in sub-optimal and inconsistent Hall Effect sensor performance.

### SUMMARY

Embodiments of the invention solve the above-mentioned problems and other problems and provide a distinct advancement in the art of Hall Effect sensor integration and placement. More particularly, the invention provides a scalable Hall Effect sensor assembly with integrated ESD protection. The invention also provides a system and method for placing Hall Effect sensors and/or Hall Effect sensor assemblies directly via their functional centers, thereby eliminating tolerance stacks associated with conventional Hall Effect sensor and/or Hall Effect sensor assembly placement.

An embodiment of the invention is a Hall Effect sensor assembly broadly comprising a substrate, a Hall Effect sensor, a first diode, and a second diode. The Hall Effect sensor assembly can be populated and manufactured in bulk and can utilize nearly any size sensor and diode combination.

The substrate supports the Hall Effect sensor, the first diode, and the second diode. The substrate includes traces, leads, solder pads, vias, landings (e.g., a voltage input interfacing landing, a signal output interfacing landing, and a ground interfacing landing), alignment fiducials, mounting features, and the like.

The Hall Effect sensor is configured to detect the presence and magnitude of a magnetic field via the Hall Effect and broadly includes a voltage input lead, a signal output lead, and a ground lead. The Hall Effect sensor is ESD-sensitive and thus is electrically connected to the first diode and the second diode to protect the Hall Effect sensor from ESD and/or other undesired voltage or current.

The voltage input lead is configured to be subjected to a voltage from a voltage source and is electrically connected to the voltage input interfacing landing. The voltage input lead is also electrically connected to the cathode of the first diode described below.

The signal output lead is configured to provide a voltage indicating a magnitude of a magnetic field. To that end, the signal output lead is electrically connected to the signal output interfacing landing. The signal output lead is also electrically connected to the cathode of the second diode described below.

The ground lead completes a circuit path for the Hall Effect sensor and is electrically connected to the ground interfacing landing. The ground lead is also electrically connected to the anode of the first diode and the anode of the second diode described below.

The first diode provides ESD protection (and/or protection from other undesired voltage or current) to the Hall Effect sensor, and specifically via the voltage input lead. To that end, the first diode is configured to shunt high voltage events to ground (i.e., ground lead and ground interfacing landing). The first diode includes an anode and a cathode.

The cathode is electrically connected to the voltage input lead of the Hall Effect sensor and the voltage input interfacing landing. The anode is electrically connected to the ground lead and the ground interfacing landing.

The second diode provides ESD protection (and/or protection from other undesired voltage or current) to the Hall Effect sensor, and specifically via the signal output lead. The second diode includes an anode and a cathode.

The cathode is electrically connected to the signal output lead of the Hall Effect sensor and the signal output interfacing landing. The anode is electrically connected to the ground lead and the ground interfacing landing.

The above-described Hall Effect sensor assembly provides several advantages. For example, the Hall Effect sensor assembly provides integrated ESD protection to the Hall Effect sensor via the diodes. It should be noted that in some instances, the Hall Effect sensor does not need ESD protection, and thus the diodes are ultimately not necessary in those instances-nevertheless, the present invention provides diodes to ensure ESD protection when it is necessary. The Hall Effect sensor assembly is scalable, and the substrate can be populated and manufactured in bulk, thus saving time and money. The substrate can accept Hall Effect sensors and diodes of any nearly any size. This simplifies circuit and circuit assembly design. The Hall Effect sensor assembly can also be incorporated into flex cable circuits.

Another embodiment of the invention is a system for locating a Hall Effect sensor assembly. The system broadly comprises an XY stage, a magnetic device, a processor, a marking device, and an altering device. For illustration, the system will be described in terms of locating the Hall Effect sensor of the Hall Effect sensor assembly described above. It should be noted, however, that the system can be used for locating any suitable Hall Effect sensor with or without accompanying diodes.

The XY stage is a tool, jig, or other similar support configured to hold the Hall Effect sensor. The XY stage is configured to be moved relative to the magnetic device (and hence relative to the Hall Effect sensor). The XY stage is also configured to move the Hall Effect sensor nominal amounts or to allow the Hall Effect sensor to be nominally repositioned for purposes of setting up movement and query tracking data collection.

The magnetic device is configured to be suspended over the XY stage and subject the Hall Effect sensor to a magnetic field. The magnetic device is a magnet or any other suitable magnetic field-generating device.

In one embodiment, the XY stage is configured to move the Hall Effect sensor while the magnetic device is stationary to effect relative movement therebetween. In another embodiment, the XY stage may be configured to hold the Hall Effect sensor stationary while the magnetic device is moved to effect relative movement therebetween. In yet another embodiment, both the XY stage and the magnetic device may be configured to be moved to effect relative movement therebetween.

The processor is communicatively coupled with motors of the XY stage to instigate movement of the XY stage (and/or motors of the magnetic device to instigate movement of the magnetic device). The processor is also communicatively coupled with the magnetic device to initiate magnetic field generation. The processor is also communicatively coupled with the marking device and altering device.

The marking device is a cutting tip or cutting blade, a laser, an ink marker or ink printer, or the like. The marking device is configured to create fiducials or other indicia on the substrate for directly or indirectly indicating a functional center of the Hall Effect sensor (and hence the Hall Effect sensor assembly).

The altering device is a cutting tip or cutting blade, a laser, a jet cutter, a heating element, or the like. The altering device is configured to cut the substrate to a particular size or shape, form holes, notches, recesses, or the like in the substrate, or form other features.

The above-described system provides several advantages. For example, the system eliminates complicated design work involved in determining proper PCB size, pad placement, pad size, and placement accuracy for accurate and repeatable placement and integration of a Hall Effect sensor and/or Hall Effect sensor assembly into an electronic circuit. The system also simplifies identification and indication (via substrate marking or modification) of a functional center of a Hall Effect sensor assembly and its Hall Effect sensor.

Another embodiment of the present invention is a method of locating a Hall Effect sensor assembly. The method will be described in terms of the system and the Hall Effect sensor of the Hall Effect sensor assembly described above. It should be noted, however, that other locating systems and Hall Effect sensor assemblies and Hall Effect sensors can be used.

First, the Hall Effect sensor is placed on the substrate. Importantly, no special or specific placement accuracies or dimensions are necessary for placement of the Hall Effect sensor on the substrate.

The Hall Effect sensor is then mounted in place on the substrate. This may entail soldering leads of the Hall Effect sensor to solder pads of the substrate, securing the Hall Effect sensor to the substrate via fasteners, or any other suitable mounting technique.

The Hall Effect sensor assembly (the Hall Effect sensor and substrate) is then positioned on the XY stage. The Hall Effect sensor assembly is also secured to the XY stage to prevent movement of the Hall Effect sensor relative to the XY stage.

With the Hall Effect sensor in the presence of a magnetic field generated by the magnetic device, the system then performs a preset search function while actively querying the Hall Effect sensor. Specifically, the XY stage (and hence the Hall Effect sensor) is moved in a search pattern while the magnetic device is stationary to effect relative movement therebetween. Alternatively and equivalently, the magnetic device may be moved relative to the XY stage (and hence relative to the Hall Effect sensor assembly). In yet another embodiment, both the XY stage and the magnetic device may be moved to effect relative movement therebetween. The relative movement may be in a single plane or according to any other suitable geometric pattern or consideration.

The processor queries the Hall Effect sensor as the magnetic field is generated in the sensing area of the Hall Effect sensor. That is, an input signal may be passed to the Hall Effect sensor so that the Hall Effect sensor generates an output signal based on the magnetic field.

The processor monitors the output signal, which may have a magnitude representative of a strength of the magnetic field at the functional center of the Hall Effect sensor assembly. The position of the XY stage or magnetic device is recorded along with sensor feedback to create a map of output based on coordinate location in a plane. The point at which the highest/peak output is achieved is deemed the functional center of the Hall Effect sensor assembly.

The functional center of the Hall Effect sensor assembly is then indicated via the substrate. This includes marking the substrate via the marking device, forming mounting features (e.g., fastener holes) or alignment features in the substrate via the altering device, or cutting the substrate to a certain size or shape based on the functional center of the Hall Effect sensor assembly. The indication step provides precise mounting characteristics (i.e., accurate location) for use in a circuit assembly.

The Hall Effect sensor assembly is then mounted on a circuit board, attached to a flex cable, or otherwise integrated into an electronic device or assembly. The functional center indication eliminates the need for customization or further design work to accommodate the Hall Effect sensor assembly.

The above-described method provides several advantages. For example, the above-described method eliminates complicated design work involved in determining proper PCB size, pad placement, pad size, and placement accuracy for integrating a Hall Effect sensor and/or Hall Effect sensor assembly into an electronic circuit. This method also simplifies identification and indication (via substrate marking or modification) of a functional center of a Hall Effect sensor assembly and its Hall Effect sensor.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present invention are described in detail below with reference to the attached drawing figures, wherein:

FIG. 1 is a schematic diagram of a Hall Effect sensor assembly constructed in accordance with an embodiment of the invention;

FIG. 2 is a circuit diagram of the Hall Effect sensor assembly of FIG. 1;

FIG. 3 is a schematic diagram of a Hall Effect sensor assembly constructed in accordance with another embodiment of the invention;

FIG. 4 is a circuit diagram of the Hall Effect sensor assembly of FIG. 3;

FIG. 5 is a schematic diagram of a system for locating a Hall Effect sensor assembly in accordance with another embodiment of the invention; and

FIG. 6 is a flow diagram depicting certain method steps of locating a Hall Effect sensor assembly in accordance with another embodiment of the invention.

The drawing figures do not limit the present invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current technology can include a variety of combinations and/or integrations of the embodiments described herein.

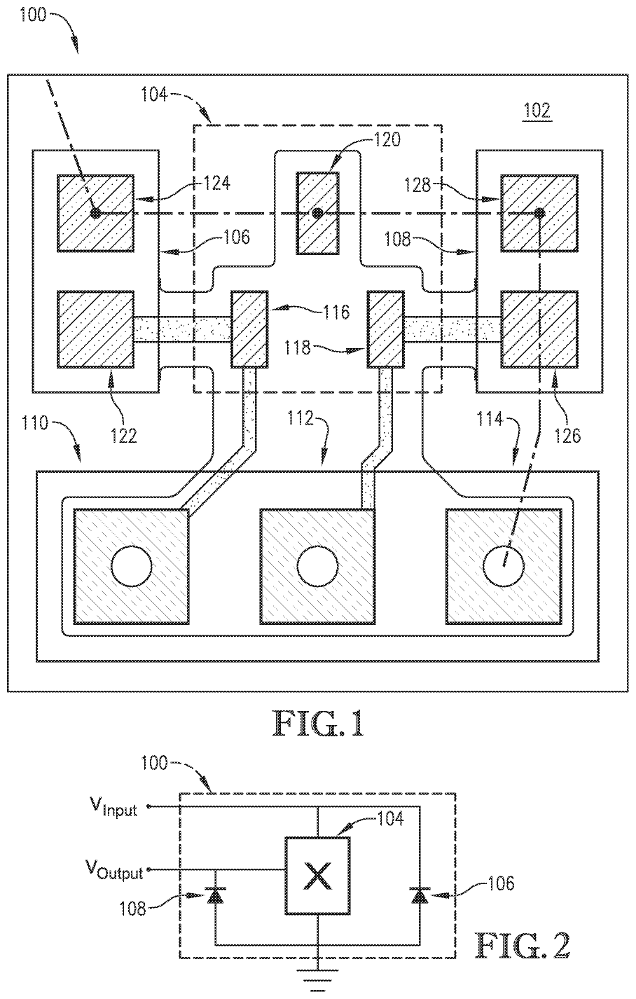

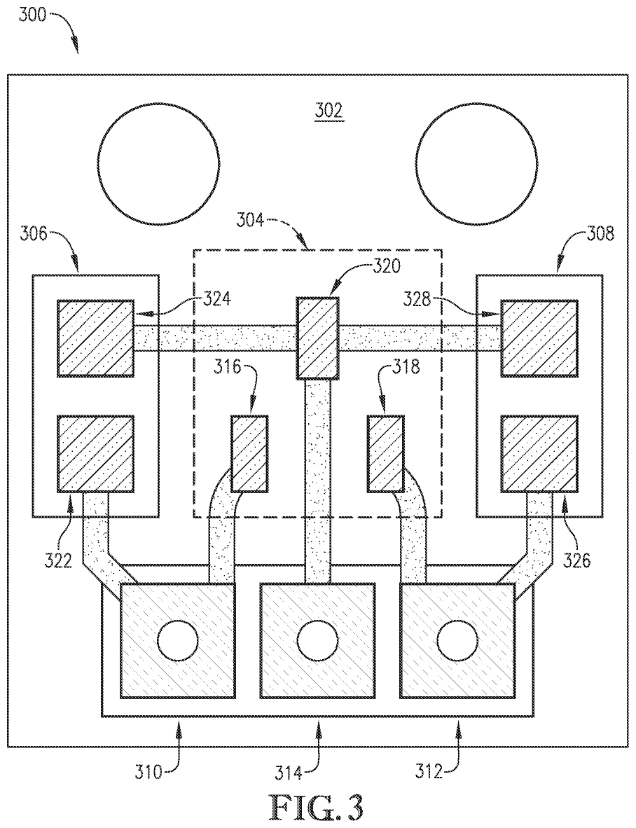

Turning to the drawing figures, and particularly FIGS. 1 and 2, a Hall Effect sensor assembly 100 constructed in accordance with an embodiment of the invention is illustrated. The Hall Effect sensor assembly 100 broadly comprises a substrate 102, a Hall Effect sensor 104, a first diode 106, and a second diode 108. The Hall Effect sensor assembly 100 may be integrated into a circuit (e.g., circuit 200) and mounted or attached to a corresponding circuit board (e.g., circuit board 202). Alternatively, the Hall Effect sensor assembly 100 may be integrated onto a flex cable or any other suitable electronic component, system, or device. The Hall Effect sensor assembly 100 provides a scalable ESD-compliant electronic assembly that can be populated and manufactured in bulk. The Hall Effect sensor assembly 100, shown in the layout of FIG. 1, is a double-sided configuration. See the Hall Effect sensor assembly 300 described below and shown in FIG. 3 for a single-sided configuration.

The substrate 102 supports the Hall Effect sensor 104, the first diode 106, and the second diode 108 and may be a printed circuit board (PCB) or printed wafer board (PWB), or the like. The substrate 102 may include traces, leads, solder pads, vias, landings (e.g., voltage input interfacing landing 110, signal output interfacing landing 112, and ground interfacing landing 114), alignment fiducials, mounting features, and the like. The substrate 102 can accept nearly any size sensor and diode combination.

The voltage input interfacing landing 110, signal output interfacing landing 112, and ground interfacing landing 114 may be aligned with each other. In this embodiment, the ground interfacing landing 114 takes an outside position (i.e., is not between the voltage input interfacing landing 110 and the signal output interfacing landing 112). Contrast this arrangement with the Hall Effect sensor assembly described below.

The Hall Effect sensor 104 is configured to detect the presence and magnitude of a magnetic field via the Hall Effect and broadly includes a voltage input lead 116, a signal output lead 118, and a ground lead 120. The Hall Effect sensor 104 may be mounted onto the substrate 102 and to that end may be soldered onto the substrate 102 via the voltage input lead 116 signal output lead 118 and ground lead 120. The Hall Effect sensor 104 may be ESD-sensitive and thus may be electrically connected to the first diode 106 and the second diode 108 to protect the Hall Effect sensor 104 from ESD and/or other undesired voltage or current. The Hall Effect sensor 104 may be an analog-bipolar Hall Effect sensor such as the DRV5053 device produced by Texas Instruments, or any other suitable Hall Effect sensor.

The voltage input lead 116 is configured to be subjected to a voltage from a voltage source. To that end, the voltage input lead 116 may be electrically connected to the voltage input interfacing landing 110. The voltage input lead 116 may also be electrically connected to the cathode of the first diode 106 described below.

The signal output lead 118 is configured to provide a voltage indicating a magnitude of a magnetic field. To that end, the signal output lead 118 may be electrically connected to the signal output interfacing landing 112. The signal output lead 118 may also be electrically connected to the cathode of the second diode 108 described below.

The ground lead 120 completes a circuit path for the Hall Effect sensor 104. To that end, the ground lead 120 may be electrically connected to the ground interfacing landing 114. The ground lead 120 may also be electrically connected to the anode of the first diode 106 and the anode of the second diode 108 described below.

The first diode 106 provides ESD protection (and/or protection from other undesired voltage or current) to the Hall Effect sensor 104, and specifically via the voltage input lead 116. To that end, the first diode 106 may be configured to shunt high voltage events to ground (i.e., ground lead 120 and ground interfacing landing 114). The first diode 106 includes a cathode 122 and an anode 124. The first diode 106 may be an ESD protection diode such as the ESD5Z2.5T1G series or SZESD5Z2.5T1G series diodes produced by ON Semiconductor®, or any other suitable diode.

The cathode 122 may be electrically connected to the voltage input lead 116 of the Hall Effect sensor 104 and the voltage input interfacing landing 110. The anode 124 may be electrically connected to the ground lead 120 and the ground interfacing landing 114.

The second diode 108 provides ESD protection (and/or protection from other undesired voltage or current) to the Hall Effect sensor 104, and specifically via the signal output lead 118. The second diode 108 includes a cathode 126 and an anode 128. The second diode 108 may be an ESD protection diode such as the ESD5Z2.5T1G series or SZESD5Z2.5T1G series diodes produced by ON Semiconductor®, or any other suitable diode.

The cathode 126 may be electrically connected to the signal output lead 118 of the Hall Effect sensor 104 and the signal output interfacing landing 114. The anode 128 may be electrically connected to the ground lead 120 and the ground interfacing landing 114.

In this embodiment (a double-sided configuration), the ground lead 120, the anode 124 of the first diode 106, the anode 128 of the second diode 108, and the ground interfacing landing 114 are shown being electrically connected out-of-plane of the substrate 102. Other arrangements maybe used, such as the one described below.

The above-described Hall Effect sensor assembly 100 provides several advantages. For example, the Hall Effect sensor assembly 100 provides integrated ESD protection to the Hall Effect sensor 104. It should be noted that in some instances, the Hall Effect sensor 104 does not need ESD protection, and thus the diodes 106, 108 are ultimately not necessary in those instances-nevertheless, the present invention provides diodes to ensure ESD protection when it is necessary. The Hall Effect sensor assembly 100 is scalable, and the substrate 102 can be populated and manufactured in bulk, thus saving time and money. The substrate 102 can accept Hall Effect sensors and diodes of any nearly any size. This simplifies circuit and circuit assembly design. The Hall Effect sensor assembly 100 can also be incorporated into flex cable circuits.

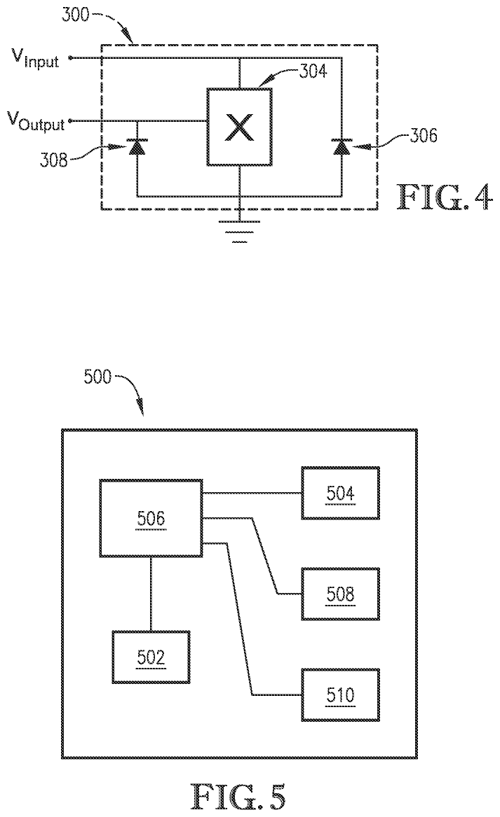

Turning to FIGS. 3 and 4, a Hall Effect sensor assembly 300 constructed in accordance with another embodiment of the invention is illustrated. The Hall Effect sensor assembly 300 broadly comprises a substrate 302, a Hall Effect sensor 304, a first diode 306, and a second diode 308.

The Hall Effect sensor assembly 300 may be integrated into a circuit (e.g., circuit 400) and mounted or attached to a corresponding circuit board (e.g., circuit board 402). Alternatively, the Hall Effect sensor assembly 300 may be integrated onto a flex cable or any other suitable electronic component, system, or device. The Hall Effect sensor assembly 300 provides a scalable ESD-compliant electronic assembly that can be populated and manufactured in bulk. The Hall Effect sensor assembly 300, shown in the layout of FIG. 3, is a single-sided configuration. See the Hall Effect sensor assembly 100 described above and shown in FIG. 1 for a single-sided configuration.

The substrate 302 supports the Hall Effect sensor 304, the first diode 306, and the second diode 308 and may be a PCB or PWB, or the like. The substrate 302 may include traces, leads, solder pads, vias, landings (e.g., voltage input interfacing landing 310, signal output interfacing landing 312, and ground interfacing landing 314), alignment fiducials, mounting features, and the like. The substrate 302 can accept nearly any size sensor and diode combination.

The voltage input interfacing landing 310, signal output interfacing landing 312, and ground interfacing landing 314 may be aligned with each other. In this embodiment, the ground interfacing landing 314 is between the voltage input interfacing landing 310 and the signal output interfacing landing 312. Contrast this arrangement with the Hall Effect sensor assembly 100 described above.

The Hall Effect sensor 304 is configured to detect the presence and magnitude of a magnetic field via the Hall Effect and broadly includes a voltage input lead 316, a signal output lead 318, and a ground lead 320. The Hall Effect sensor 304 may be mounted onto the substrate 302 and to that end may be soldered onto the substrate 302 via the voltage input lead 316 signal output lead 318 and ground lead 320. The Hall Effect sensor 304 may be ESD-sensitive and thus may be electrically connected to the first diode 306 and the second diode 308 to protect the Hall Effect sensor 304 from ESD and/or other undesired voltage or current. The Hall Effect sensor 304 may be an analog-bipolar Hall Effect sensor such as the DRV5053 device produced by Texas Instruments, or any other suitable Hall Effect sensor.

The voltage input lead 316 is configured to be subjected to a voltage from a voltage source. To that end, the voltage input lead 316 may be electrically connected to the voltage input interfacing landing 310. The voltage input lead 316 may also be electrically connected to the cathode of the first diode 306 described below.

The signal output lead 318 is configured to provide a voltage indicating a magnitude of a magnetic field. To that end, the signal output lead 318 may be electrically connected to the signal output interfacing landing 312. The signal output lead 318 may also be electrically connected to the cathode of the second diode 308 described below.

The ground lead 320 completes a circuit path for the Hall Effect sensor 304. To that end, the ground lead 320 may be electrically connected to the ground interfacing landing 314. The ground lead 320 may also be electrically connected to the anode of the first diode 306 and the anode of the second diode 308 described below.

The first diode 306 provides ESD protection (and/or protection from other undesired voltage or current) to the Hall Effect sensor 304, and specifically via the voltage input lead 316. To that end, the first diode 306 may be configured to shunt high voltage events to ground (i.e., ground lead 320 and ground interfacing landing 314). The first diode 306 includes a cathode 322 and an anode 324. The first diode 306 may be an ESD protection diode such as the ESD5Z2.5T1G series or SZESD5Z2.5T1G series diodes produced by ON Semiconductor®, or any other suitable diode.

The cathode 322 may be electrically connected to the voltage input lead 316 of the Hall Effect sensor 304 and the voltage input interfacing landing 310. The anode 324 may be electrically connected to the ground lead 320 and the ground interfacing landing 314.

The second diode 308 provides ESD protection (and/or protection from other undesired voltage or current) to the Hall Effect sensor 304, and specifically via the signal output lead 318. The second diode 308 includes a cathode 326 and an anode 328. The second diode 308 may be an ESD protection diode such as the ESD5Z2.5T1G series or SZESD5Z2.5T1G series diodes produced by ON Semiconductor®, or any other suitable diode.

The cathode 326 may be electrically connected to the signal output lead 318 of the Hall Effect sensor 304 and the signal output interfacing landing 314. The anode 328 may be electrically connected to the ground lead 320 and the ground interfacing landing 314.

In this embodiment, the ground lead 320, the cathode 322 of the first diode 306, the cathode 326 of the second diode 308, and the ground interfacing landing 314 are shown being electrically connected in-plane on the substrate 302. In addition to this and the out-of-plane embodiment described previously (see Hall Effect sensor assembly 100 above), other arrangements maybe used.

Turning to FIG. 5, a system 500 for locating a Hall Effect sensor assembly in accordance with another embodiment of the invention is illustrated. The system 500 broadly comprises an XY stage 502, a magnetic device 504, a processor 506, a marking device 508, and an altering device 510. For illustration, the system 500 will be described in terms of locating the Hall Effect sensor 104 of the Hall Effect sensor assembly 100 described above. It should be noted, however, that the system 500 can be used for locating any suitable Hall Effect sensor with or without accompanying diodes.

The XY stage 502 may be a tool, jig, or other similar support configured to hold the Hall Effect sensor 104. The XY stage 502 may be configured to be moved relative to the magnetic device 504 (and hence relative to the Hall Effect sensor 104). The XY stage 502 may also be configured to move the Hall Effect sensor 104 nominal amounts or may be configured to allow the Hall Effect sensor 104 to be nominally repositioned for purposes of setting up movement and query tracking data collection.

The magnetic device 504 may be configured to be suspended over the XY stage 502 and subject the Hall Effect sensor 104 to a magnetic field. The magnetic device 504 may be a magnet or any other suitable magnetic field-generating device.

In one embodiment, the XY stage 502 is configured to move the Hall Effect sensor 104 while the magnetic device 504 is stationary to effect relative movement therebetween. In another embodiment, the XY stage 502 may be configured to hold the Hall Effect sensor 104 stationary while the magnetic device 504 is moved to effect relative movement therebetween. In yet another embodiment, both the XY stage 502 and the magnetic device 504 may be configured to be moved to effect relative movement therebetween.

The processor 506 may be communicatively coupled with motors of the XY stage to instigate movement of the XY stage (and/or motors of the magnetic device 504 to instigate movement of the magnetic device 504). The processor 506 may also be communicatively coupled with the magnetic device 504 to initiate magnetic field generation. The processor 506 may also be communicatively coupled with the marking device 508 and altering device 510.

The processor 506 may implement aspects of the present invention with one or more computer programs stored in or on computer-readable medium residing on or accessible by the processor. Each computer program preferably comprises an ordered listing of executable instructions for implementing logical functions in the processor. Each computer program can be embodied in any non-transitory computer-readable medium, such as the memory (described below), for use by or in connection with an instruction execution system, apparatus, or device, such as a computer-based system, processor-containing system, or other system that can fetch the instructions from the instruction execution system, apparatus, or device, and execute the instructions.

The memory may be any computer-readable non-transitory medium that can store the program for use by or in connection with the instruction execution system, apparatus, or device. The computer-readable medium can be, for example, but not limited to, an electronic, magnetic, optical, electro-magnetic, infrared, or semi-conductor system, apparatus, or device. More specific, although not inclusive, examples of the computer-readable medium would include the following: an electrical connection having one or more wires, a portable computer diskette, a random access memory (RAM), a read-only memory (ROM), an erasable, programmable, read-only memory (EPROM or Flash memory), an optical fiber, and a portable compact disk read-only memory (CDROM).

The marking device 508 may be a cutting tip or cutting blade, a laser, an ink marker or ink printer, or the like. The marking device 508 may be configured to create fiducials or other indicia on the substrate 102 for directly or indirectly indicating a functional center of the Hall Effect sensor 104 (and hence the Hall Effect sensor assembly 100).

The altering device 510 may be a cutting tip or cutting blade, a laser, a jet cutter, a heating element, or the like. The altering device 510 may be configured to cut the substrate 102 to a particular size or shape, form holes, notches, recesses, or the like in the substrate 102, or form other features.

The above-described system 500 provides several advantages. For example, the system 500 eliminates complicated design work involved in determining proper PCB size, pad placement, pad size, and placement accuracy for integrating a Hall Effect sensor and/or Hall Effect sensor assembly into an electronic circuit. The system 500 also simplifies identification and indication (via substrate marking or modification) of a functional center of a Hall Effect sensor assembly and its Hall Effect sensor.

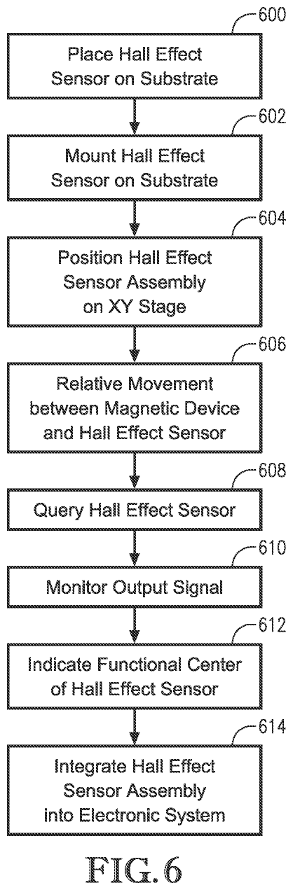

Turning to FIG. 6, a method of locating a Hall Effect sensor assembly in accordance with another embodiment of the invention is illustrated. For illustration, the method will be described in terms of the system 500 and the Hall Effect sensor 104 of the Hall Effect sensor assembly 100 described above. It should be noted, however, that other locating systems and Hall Effect sensor assemblies and Hall Effect sensors can be used.

First, the Hall Effect sensor 104 may be placed on the substrate 102, as shown in block 600. Importantly, no special or specific placement accuracies or dimensions are necessary for placement of the Hall Effect sensor 104 on the substrate 102.

The Hall Effect sensor 104 may then be mounted in place on the substrate 102, as shown in block 602. This may entail soldering leads of the Hall Effect sensor 104 to solder pads of the substrate 102, securing the Hall Effect sensor 104 to the substrate 102 via fasteners, or any other suitable mounting technique.

The Hall Effect sensor assembly 100 (the Hall Effect sensor 104 and substrate 102) may then be positioned on the XY stage 502, as shown in block 604. The Hall Effect sensor assembly 100 may also be secured to the XY stage 502 to prevent movement of the Hall Effect sensor 104 relative to the XY stage 502. In one embodiment, coordinates of the XY stage 502 indicating a position of the Hall Effect sensor 104 may be obtained by the processor 506.

With the Hall Effect sensor 104 in the presence of a magnetic field generated by the magnetic device 504, the system 500 then performs a preset search function while actively querying the Hall Effect sensor 104. Specifically, the XY stage 502 (and hence the Hall Effect sensor 104) is moved in a search pattern while the magnetic device 504 is stationary to effect relative movement therebetween. Alternatively and equivalently, the magnetic device 504 may be moved relative to the XY stage 502 (and hence relative to the Hall Effect sensor assembly 100), as shown in block 606. In yet another embodiment, both the XY stage 502 and the magnetic device 504 may be moved to effect relative movement therebetween. The relative movement may be in a single plane or according to any other suitable geometric pattern or consideration.

The processor 506 may query the Hall Effect sensor 104 as the magnetic field is generated in the sensing area of the Hall Effect sensor 104, as shown in block 608. That is, an input signal may be passed to the Hall Effect sensor 104 so that the Hall Effect sensor 104 generates an output signal based on the magnetic field.

The processor 506 may monitor the output signal, as shown in block 610. The output signal may have a magnitude representative of a strength of the magnetic field at the functional center of the Hall Effect sensor assembly 100. The position of the XY stage 502 or magnetic device 504 is recorded along with sensor feedback to create a map of output based on coordinate location in a plane. The point at which the highest/peak output is achieved is deemed the functional center of the Hall Effect sensor assembly 100.

The functional center of the Hall Effect sensor assembly 100 may then be indicated via the substrate 102, as shown in block 612. This may include marking the substrate 102 via the marking device 508, forming mounting features (e.g., fastener holes) or alignment features in the substrate 102 via the altering device 510, or cutting the substrate 102 to a certain size or shape based on the functional center of the Hall Effect sensor assembly 100. The indication step provides precise mounting characteristics (i.e., accurate location) for use in a circuit assembly.

The Hall Effect sensor assembly 100 may then be mounted on a circuit board, attached to a flex cable, or otherwise integrated into an electronic device or assembly, as shown in block 614. The functional center indication eliminates the need for customization or further design work to accommodate the Hall Effect sensor assembly 100.

The above-described method provides several advantages. For example, the above-described method eliminates complicated design work involved in determining proper PCB size, pad placement, pad size, and placement accuracy for integrating a Hall Effect sensor and/or Hall Effect sensor assembly into an electronic circuit. This method also simplifies identification and indication (via substrate marking or modification) of a functional center of a Hall Effect sensor assembly and its Hall Effect sensor.

### ADDITIONAL CONSIDERATIONS

The description and drawings are illustrative and are not to be construed as limiting. Numerous specific details are described to provide a thorough understanding. However, in certain instances, well-known or conventional details are not described in order to avoid obscuring the description. References to one embodiment or an embodiment in the present disclosure are not necessarily references to the same embodiment; and, such references mean at least one.

The use of headings herein is merely provided for ease of reference, and shall not be interpreted in any way to limit this disclosure or the following claims.

References to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, and are not necessarily all referring to separate or alternative embodiments mutually exclusive of other embodiments. Moreover, various features are described which may be exhibited by one embodiment and not by others. Similarly, various requirements are described which may be requirements for one embodiment but not for other embodiments. Unless excluded by explicit description and/or apparent incompatibility, any combination of various features described in this description is also included here.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

Although the invention has been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A method of locating a Hall Effect sensor assembly, the method comprising:
moving at least one of a magnetic device and a Hall Effect sensor of the Hall Effect sensor assembly to effect relative movement between the magnetic device and the Hall Effect sensor in a plane;
querying the Hall Effect sensor as relative movement between the magnetic device and the Hall Effect sensor is effected;
monitoring an output of the Hall Effect sensor in response to the querying step;
identifying a functional center of the Hall Effect sensor assembly based on a peak of the output of the Hall Effect sensor; and
indicating the functional center of the Hall Effect sensor assembly via a substrate of the Hall Effect sensor assembly for integrating the Hall Effect sensor assembly into a circuit assembly.

2. The method of claim 1, the indicating step including marking the substrate.

3. The method of claim 2, the indicating step including laser marking the substrate.

4. The method of claim 1, the indicating step including physically altering the substrate.

5. The method of claim 4, the indicating step including at least one of forming alignment fiducials in the substrate or altering dimensions of the substrate.

6. The method of claim 1, the Hall Effect sensor assembly including a diode electrically connected to the Hall Effect sensor and configured to shunt high voltage events thereby protecting the Hall Effect sensor.

7. The method of claim 6, the diode being mounted to the substrate.

8. The method of claim 1, the substrate being a circuit board.

9. The method of claim 8, at least a portion of the Hall Effect sensor being printed on the circuit board.

10. The method of claim 1, the Hall Effect sensor assembly including:
a first diode mounted on the substrate and electrically connected to a supply voltage node of the Hall Effect sensor assembly; and
a second diode mounted on the substrate and electrically connected to an output node of the Hall Effect sensor assembly,
the first and second diodes being configured to shunt high voltage events to the ground node thereby protecting the Hall Effect sensor.

11. A method of locating a Hall Effect sensor assembly onto a circuit board, the method comprising:
moving at least one of a magnetic device and a Hall Effect sensor of the Hall Effect sensor assembly to effect relative movement between the magnetic device and the Hall Effect sensor in a plane;
querying the Hall Effect sensor as relative movement between the magnetic device and the Hall Effect sensor is effected;
monitoring an output of the Hall Effect sensor in response to the querying step;
identifying a functional center of the Hall Effect sensor assembly based on a peak of the output of the Hall Effect sensor;
indicating the functional center of the Hall Effect sensor assembly via a substrate of the Hall Effect sensor assembly; and
mounting the Hall Effect sensor assembly onto a circuit board based on the functional center of the Hall Effect sensor assembly.

12. The method of claim 11, the indicating step including marking the substrate.

13. The method of claim 12, the indicating step including laser marking the substrate.

14. The method of claim 11, the indicating step including physically altering the substrate.

15. The method of claim 14, the indicating step including at least one of forming alignment fiducial holes in the substrate or altering dimensions of the substrate.

16. The method of claim 11, the Hall Effect sensor assembly including a diode electrically connected to the Hall Effect sensor and configured to shunt high voltage events thereby protecting the Hall Effect sensor.

17. The method of claim 16, the diode being mounted to the substrate.

18. The method of claim 11, the substrate being a circuit board.

19. The method of claim 18, at least a portion of the Hall Effect sensor being printed on the circuit board substrate.

20. A method of locating a Hall Effect sensor assembly, the method comprising:
moving at least one of a magnetic device and a Hall Effect sensor of the Hall Effect sensor assembly to effect relative movement between the magnetic device and the Hall Effect sensor in a plane;
querying the Hall Effect sensor as relative movement between the magnetic device and the Hall Effect sensor is effected;
monitoring an output of the Hall Effect sensor in response to the querying step;
identifying a functional center of the Hall Effect sensor assembly based on a peak of the output of the Hall Effect sensor;
indicating the functional center of the Hall Effect sensor assembly via a substrate of the Hall Effect sensor assembly; and
mounting the Hall Effect sensor assembly onto a circuit board based on the functional center of the Hall Effect sensor assembly,
the Hall Effect sensor assembly comprising:
a first diode mounted on the substrate and electrically connected to a supply voltage node of the Hall Effect sensor assembly; and
a second diode mounted on the substrate and electrically connected to an output node of the Hall Effect sensor assembly,
the first and second diodes being configured to shunt high voltage events to the ground node thereby protecting the Hall Effect sensor.
